(19) United States
(12) Patent Application Publication
(10) Pub. No.: US 2025/0089341 A1
(43) Pub. Date: Mar. 13, 2025

(54) NON-VOLATILE MEMORY DEVICE AND METHOD OF MANUFACTURING THE SAME

(71) Applicant: Samsung Electronics Co., Ltd., Suwon-si (KR)

(72) Inventors: Hoseok HEO, Suwon-si (KR); Minhyun LEE, Suwon-si (KR); Sangwon KIM, Suwon-si (KR); Seyun KIM, Suwon-si (KR); Seokhoon CHOI, Suwon-si (KR)

(73) Assignee: Samsung Electronics Co., Ltd., Suwon-si (KR)

(21) Appl. No.: 18/818,855

(22) Filed: Aug. 29, 2024

(30) Foreign Application Priority Data
Sep. 8, 2023 (KR) 10-2023-0119613

(51) Int. Cl. H01L 29/49; G11C 16/04; H01L 21/28; H10B 43/27

(52) U.S. Cl. CPC H10D 64/665; G11C 16/0483; H10B 43/27; H10D 64/037

(57) ABSTRACT

A non-volatile memory device may include a channel layer extending in a first direction, a plurality of gate electrodes and a plurality of insulating layers spaced apart from the channel layer and alternately arranged in the first direction, a charge trap layer between the channel layer and the plurality of gate electrodes, and a charge tunneling layer between the channel layer and the charge trap layer. The plurality of gate electrodes may include M, A, and X, where M may include a metal; A may include a Group 13 element, a Group 14 element, or V, or a combination thereof; X may include carbon or nitrogen, and M, A, and X may be arranged to have a layered crystal structure.

### CROSS-REFERENCE TO RELATED APPLICATION

This application is based on and claims priority under 35 U.S.C. § 119 to Korean Patent Application No. 10-2023-0119613, filed on Sep. 8, 2023 in the Korean Intellectual Property Office, the disclosure of which is incorporated by reference herein in its entirety.

### BACKGROUND

### 1. Field

The disclosure relates to a non-volatile memory device and a method of manufacturing the same.

### 2. Description of the Related Art

Non-volatile memory devices may include semiconductor memory devices in which stored data is not lost even when the supply of power is interrupted, and may include, for example, Programmable ROMs (PROMs), Erasable Programmable PROMs (EPROMs), Electrically Erasable Programmable EPROMs (EEPROMs), flash memory devices, and the like.

In order to increase the capacity of non-volatile memory devices, it may be necessary to increase cell density by improving resistivity while limiting and/or preventing reaction or diffusion between interfaces.

### SUMMARY

Provided are a non-volatile memory device that limits and/or prevents reaction or diffusion between interfaces and has improved resistivity, and a method of manufacturing the same.

Additional aspects will be set forth in part in the description which follows and, in part, will be apparent from the description, or may be learned by practice of the presented embodiments of the disclosure.

According to an embodiment of inventive concepts, a non-volatile memory device may include a channel layer extending in a first direction, a plurality of gate electrodes and a plurality of insulating layers spaced apart from the channel layer and alternately arranged in the first direction, a charge trap layer between the channel layer and the plurality of gate electrodes, and a charge tunneling layer between the channel layer and the charge trap layer. The plurality of gate electrodes may include M, A, and X, where M may include a metal; A may include a Group 13 element, a Group 14 element, or V, or a combination thereof; X may include carbon or nitrogen, and M, A, and X may be arranged to have a layered crystal structure.

In some embodiments, each of the plurality of gate electrodes may include M₂AX, M₃AX₂, or M₄AX₃, or a combination thereof.

In some embodiments, M may include Cr, Ti, V, Ta, Mo, Hf, or Zr, or a combination thereof.

In some embodiments, A may include Si, Al, Ga, In, Ge, Sn, or V, or a combination thereof.

In some embodiments, an out-of-plane direction of the layered crystal structure may be parallel to the first direction.

In some embodiments, an out-of-plane direction of the layered crystal structure may be perpendicular to the first direction.

In some embodiments, the non-volatile memory device may further include a diffusion barrier layer between the plurality of gate electrodes and the plurality of insulating layers.

In some embodiments, the non-volatile memory device may further include a diffusion barrier layer between the plurality of gate electrodes and the charge trap layer.

In some embodiments, the non-volatile memory device may further include a diffusion barrier layer between the plurality of gate electrodes and the plurality of insulating layers and between the plurality of gate electrodes and the charge trap layer.

In some embodiments, the non-volatile memory device may further include a charge blocking layer between the charge trap layer and the plurality of gate electrodes.

According to an embodiment of inventive concepts, a method of manufacturing a non-volatile memory device may include alternately stacking a plurality of sacrificial layers and a plurality of insulating layers in a first direction, forming a channel hole by etching through a region of the plurality of sacrificial layers and the plurality of insulating layers, providing a charge trap layer on an inner surface of the channel hole, providing a charge tunneling layer on an inner surface of the charge trap layer, providing a channel layer on an inner surface of the charge tunneling layer, and removing the plurality of sacrificial layers and providing a plurality of gate electrodes in an area in which the plurality of sacrificial layers were removed. Each of the plurality of gate electrodes may include M, A, and X, where M may include a metal; A may include a Group 13 element, a Group 14 element, V, or a combination thereof; X may include carbon or nitrogen; and M, A, and X may be arranged to have a layered crystal structure.

In some embodiments, each of the plurality of gate electrodes may include M₂AX, M₃AX₂, or M₄AX₃, or a combination thereof.

In some embodiments, M may include Cr, Ti, V, Ta, Mo, Hf, or Zr, or a combination thereof.

In some embodiments, A may include Si, Al, Ga, In, Ge, Sn, or V, or a combination thereof.

In some embodiments, an out-of-plane direction of the layered crystal structure may be parallel to the first direction.

In some embodiments, an out-of-plane direction of the layered crystal structure may be perpendicular to the first direction.

In some embodiments, the method may further include providing a diffusion barrier layer between the plurality of gate electrodes and the plurality of insulating layers or between the plurality of gate electrodes and the charge trap layer.

The method may further include providing a charge blocking layer between the charge trap layer and the plurality of gate electrodes.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a schematic structure of a non-volatile memory device according to an embodiment;

FIG. 2 is a perspective view showing a schematic structure of a memory string provided in the non-volatile memory device of FIG. 1;

FIGS. 3 to 10 are cross-sectional views showing a schematic structure of a memory cell;

FIGS. 11A to 11F are diagram showings examples of M, A, and X constituting a gate electrode;

FIG. 12 is an equivalent circuit diagram of the non-volatile memory device of FIG. 1;

FIGS. 13 to 19D are reference views for describing a method of manufacturing a non-volatile memory device, according to an embodiment;

FIG. 20 is a flowchart illustrating a procedure for manufacturing a non-volatile memory device, according to an embodiment;

FIG. 21 is a block diagram schematically describing an electronic apparatus including a non-volatile memory device according to an embodiment;

FIG. 22 is a block diagram schematically describing a memory system including a non-volatile memory device according to an embodiment; and

FIG. 23 is a block diagram schematically illustrating a neuromorphic device including a memory device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, embodiments will be described in detail with reference to the accompanying drawings. Embodiments to be described below are only examples and various modifications from such embodiments may be possible. Like reference numerals in the drawings denote like components, and sizes of components in the drawings may be exaggerated for convenience of explanation.

Hereinafter, the term “on” or “above” may include not only one directly above another in contact but also one directly above another without contact.

The terms first, second, etc. may be used to describe various components, but are used only for the purpose of distinguishing one component from another component. These terms are not intended to limit the material or structure of the components.

Singular expressions include plural expressions unless they are explicitly and differently specified in context. In addition, when a certain portion is referred to as “including” any component, this means that other components can be further included, rather than excluding other components unless otherwise stated.

Also, in the specification, the term “units” or “ . . . modules” denote units or modules that process at least one function or operation, and may be realized by hardware, software, or a combination of hardware and software.

The use of the term “the” and similar instruction terms may correspond to both singular and plural.

If there is no obvious indication that the steps of configuring the method should be done in the stated order, it can be done in a suitable order. In addition, the use of all example terms (e.g., etc.) is merely for describing technical ideas in detail and is not limited by the claims, and thus the scope of rights is not limited by the term.

A non-volatile memory device according to the present embodiment may be a vertical NAND (VNAND) memory in which a plurality of memory cells MC are arrayed in a vertical direction.

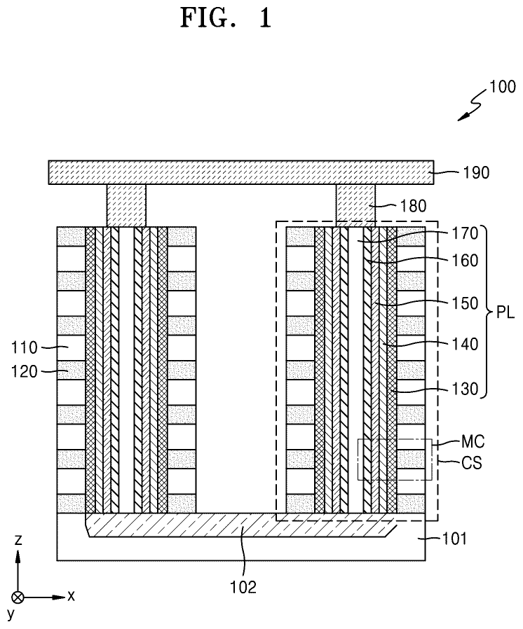

The detailed configuration of the non-volatile memory device will be described below with reference to FIGS. 1 to 11F.

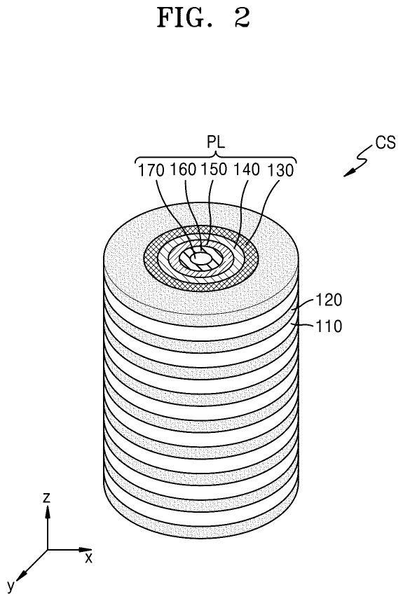

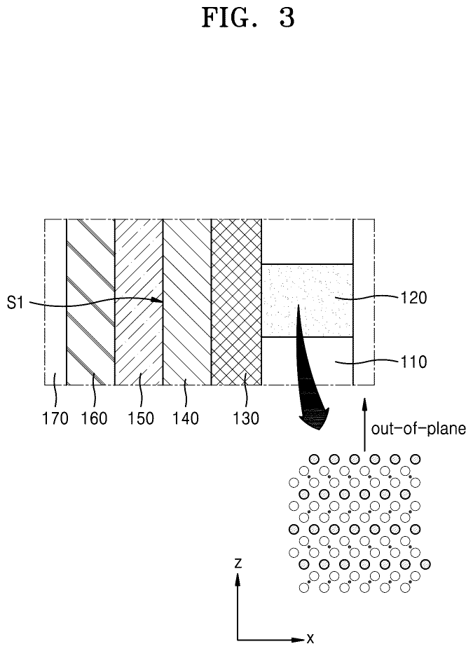

FIG. 1 is a cross-sectional view showing a schematic structure of a non-volatile memory device 100 according to an embodiment, and FIG. 2 is a perspective view showing a schematic structure of a memory string provided in the non-volatile memory device 100 of FIG. 1. FIG. 3 is a cross-sectional view showing a schematic structure of a memory cell MC of FIG. 1.

Referring to FIG. 1, a plurality of cell strings CS may be provided on a substrate 101. Referring to FIG. 2, each of the plurality of cell strings CS may include a cylindrical pillar PL, a plurality of insulating layers 110 and a plurality of gate electrodes 120, which surround the pillar PL in a ring form. The plurality of insulating layers 110 and the plurality of gate electrodes 120 may be alternately stacked on one another in a direction perpendicular to the substrate 101. However, the pillar PL is not limited to a cylindrical shape.

The substrate 101 may include a silicon material doped with a first type impurity. For example, the substrate 101 may include a silicon material doped with a p-type impurity. For example, the substrate 101 may be a p-type well (e.g., a pocket p-well). Hereinafter, it may be assumed that the substrate 101 is p-type silicon. However, the substrate 101 is not limited to the p-type silicon.

A doping region 102 may be on the substrate 101. For example, the doping region 102 may have a second type impurity that is different from that of the substrate 101. For example, the doping region 102 may have an n-type impurity. Hereinafter, it may be assumed that the doping region 102 is of an n-type. Hereinafter, the doping region 102 is not limited to the n-type. The doping region 102 may be connected to a common source line CSL.

The insulating layers 110 may function as spacers for insulation between conductive layers. The insulating layers 110 not only may function as spacers for maintaining a distance between the gate electrodes 120 but also may limit and/or prevent charges trapped in the charge trap layer 140 from spreading toward another cell. The insulating layers 110 may include various insulating materials such as a silicon oxide, a silicon nitride, and the like. The insulating layers 110 may include one or more layers.

The gate electrodes 120 may include metal materials or heavily doped silicon materials. Each of the gate electrodes 120 may be connected to one of a word line WL and a string selection line SSL. Here, referring to FIGS. 1 to 3 together, the gate electrode 120 may include M, A, and X arranged to have a layered crystal structure. The entire area or a partial area of the gate electrode 120 may have a layered crystal structure. Here, M may include a metal, A may include a Group 13 element, a Group 14 element, a Group 15 element, or vanadium (V), or a combination thereof, and X may include carbon or nitrogen.

The above-mentioned M may include chromium (Cr), titanium (Ti), vanadium (V), tantalum (Ta), molybdenum (Mo), hafnium (Hf), zirconium (Zr), or a combination thereof. The above-mentioned A may include silicon (Si), aluminum (Al), gallium (Ga), indium (In), germanium (Ge), arsenic (As), tin (Sn), vanadium (V), or cadmium (Cd), or a combination thereof.

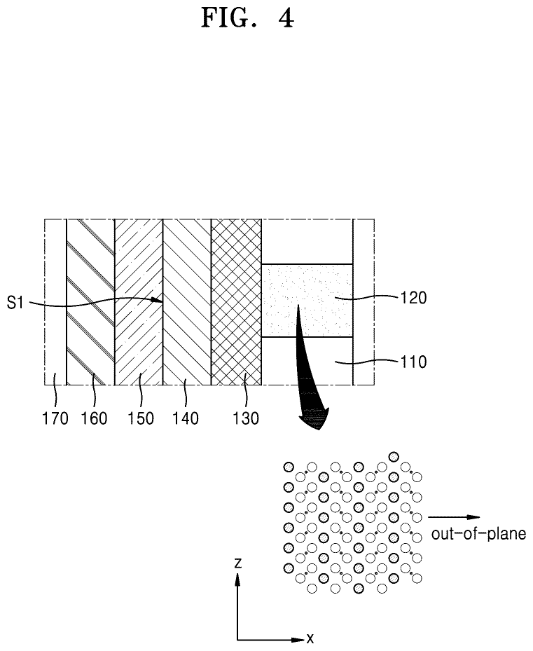

As shown in FIG. 3, the in-plane of the layered crystal structure may be perpendicular to a direction (for example, a Z direction) in which a channel layer 160 extends, and an out-of-plane direction of the layered structure may be parallel to the Z direction. The out-of-plane direction may represent a direction perpendicular to one plane of the layered crystal structure. Alternatively, as shown in FIG. 4, the plane of the layered crystal structure may be parallel to the direction (for example, the Z direction) in which the channel layer 160 extends, and the out-of-plane direction of the layered structure may be perpendicular to the Z direction.

The pillar PL may include a plurality of layers. For example, a charge blocking layer 130, a charge trap layer 140, a charge tunneling layer 150, and a channel layer 160 may be sequentially provided on the pillar PL. Here, when a certain voltage is applied to the gate electrodes 120, charges flowing between a source and drain 180 of the channel 160 may pass through the charge tunneling layer 150 and may be captured in the charge trap layer 140 so that information may be stored.

Each of the charge blocking layer 130, the charge trap layer 140, and the charge tunneling layer 150 may extend in a direction perpendicular to the surface of the substrate 101. Each of the charge blocking layer 130, the charge trap layer 140, and the charge tunneling layer 150 may have a cylindrical shape, but is not limited thereto.

The charge blocking layer 130 may be conformally provided in the pillar PL. The charge blocking layer 130 may be provided to be in contact with the insulating layers 110 and the gate electrodes 120. The charge blocking layer 130 may function as a barrier for limiting and/or preventing charge movement between the charge trap layer 140 and the gate electrode 120. A first surface of the charge blocking layer 130 may be in contact with the charge trap layer 140, and a second surface facing the first surface may be in contact with the gate electrode 120. The charge blocking layer 130 may include, for example, a silicon oxide or a metal oxide, but embodiments are not limited thereto. The charge blocking layer 130 may be omitted.

The charge trap layer 140 may be provided along an inner surface of the charge blocking layer 130. The charge trap layer 140 may store introduced charges. The charges (e.g., electrons) that are present in the channel layer 160 may be introduced into the charge trap layer 140 due to a tunneling effect or the like. The charges introduced into the charge trap layer 140 may be fixed in the charge trap layer 140.

The charge tunneling layer 150 may be provided along an inner surface of the charge trap layer 140. The charge tunneling layer 150 may be a layer in which charge tunneling is performed, for example, a silicon oxide or a metal oxide, but embodiments are not limited thereto.

The channel layer 160 may be conformally provided along the inner surface of the charge tunneling layer 150. The channel layer 160 may include a semiconductor material doped with a first type impurity. The channel layer 160 may include a silicon material doped with the same type impurity as that of the substrate 101, and for example, when the substrate 101 includes a silicon material doped with a p-type impurity, the channel layer 160 may also include a silicon material doped with the p-type impurity. Alternatively, the channel layer 160 may include a material such as germanium (Ge), indium gallium zinc oxide (IGZO), gallium arsenide (GaAs), or the like. The channel layer 160 may have a cylindrical shape.

The filling layer 170 may be conformally provided along the inner surface of the channel layer 160. The filling layer 170 may include, for example, a silicon oxide or air, but embodiments are not limited thereto.

The channel layer 160 may be in contact with the doping region 102, e.g., a common source region.

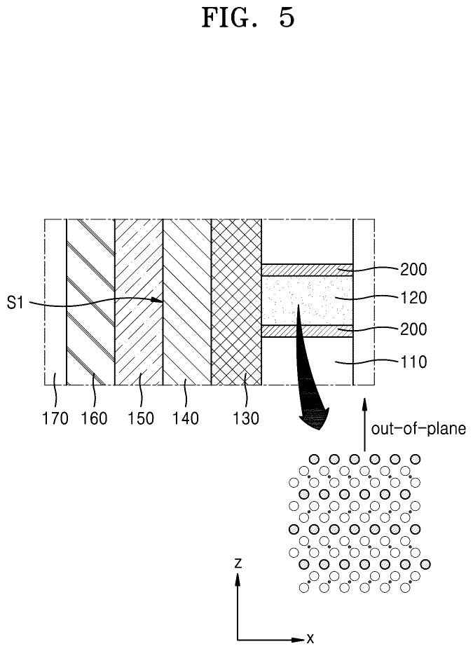

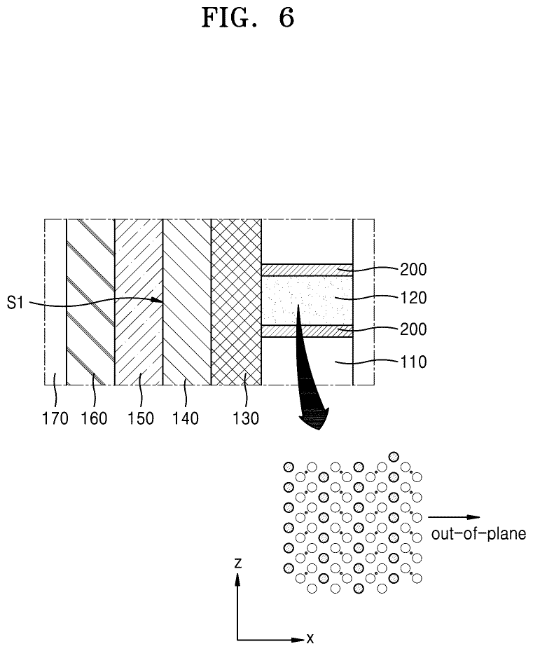

Referring to FIGS. 5 and 6, a diffusion barrier layer 200 may be provided between the gate electrode 120 and the insulating layer 110. As in FIGS. 3 and 4, the out-of-plane direction of the layered crystal structure may be parallel to the Z direction as shown in FIG. 5 or perpendicular to the Z direction as shown in FIG. 6.

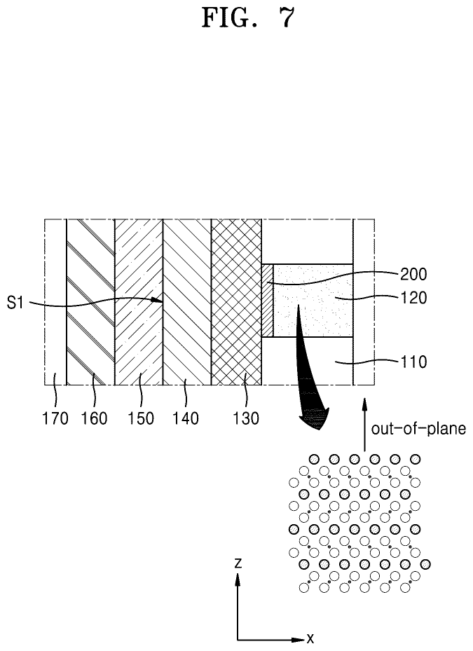

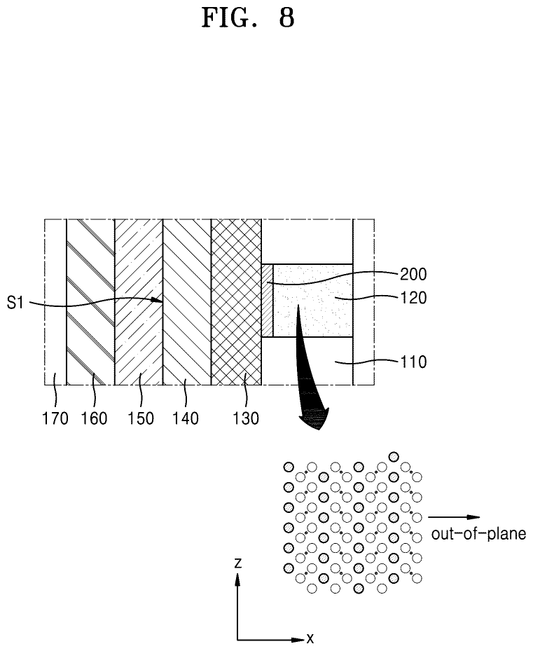

Referring to FIGS. 7 and 8, a diffusion barrier layer 200 may be provided between the gate electrode 120 and the charge blocking layer 130. When the charge blocking layer 130 is omitted, a diffusion barrier layer 200 may be provided between the gate electrode 120 and the charge trap layer 140. Here, as in FIGS. 3 and 4, the out-of-plane direction of the layered crystal structure may be parallel to the Z direction as shown in FIG. 7 or perpendicular to the Z direction as shown in FIG. 8.

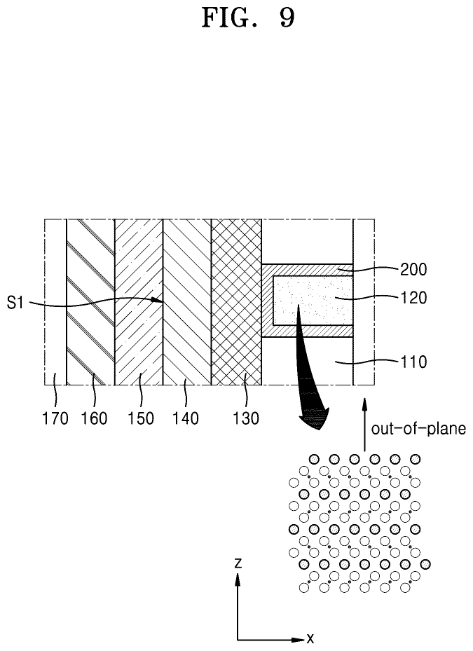

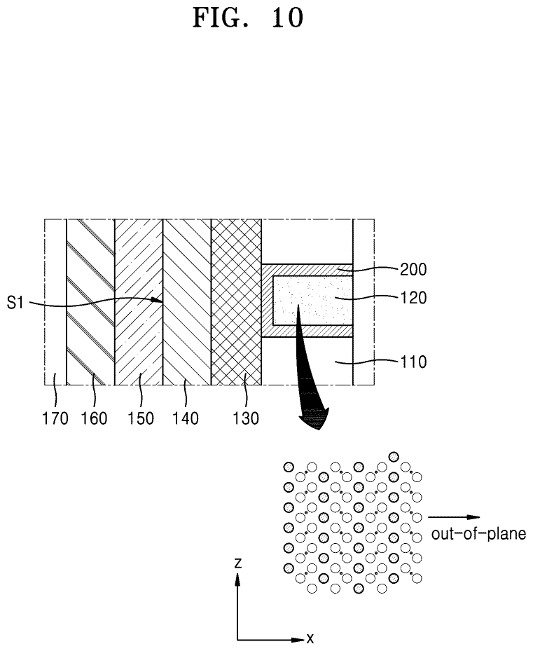

Referring to FIGS. 9 and 10, a diffusion barrier layer 200 may be provided between the gate electrode 120 and the insulating layer 110 and between the gate electrode 120 and the charge blocking layer 130. When the charge blocking layer 130 is omitted, a diffusion barrier layer 200 may be provided between the gate electrode 120 and the insulating layer 110 and between the gate electrode 120 and the charge trap layer 140. Here, as in FIGS. 3 and 4, the out-of-plane direction of the layered crystal structure may be parallel to the Z direction as shown in FIG. 9 or perpendicular to the Z direction as shown in FIG. 10.

The diffusion barrier layer 200 described above may limit and/or prevent reaction and diffusion between interfaces between the gate electrode 120 and the insulating layer 110 or the gate electrode 120 and the charge trap layer 140. The diffusion barrier layer 200 may include a material whose oxide has a higher redox potential than the constituent material (for example, SiO₂) of the insulating layer 110. For example, the diffusion barrier layer 200 may include Ti, Zr, V, Al, lanthanum (La), niobium (Nb), tantalum (Ta), or a combination thereof.

The drain 180 may be provided on the pillar PL. The drain 180 may include a silicon material doped with a second type impurity. For example, the drain 180 may include a silicon material doped with an n-type impurity.

A bit line 190 may be provided on the drain 180. The drain 180 and bit lines 190 and 550 may be connected to each other via contact plugs.

Each gate electrode 120 and the channel layer 160 facing each gate electrode 120 in a horizontal direction with respect to the substrate 101 may constitute the memory cell MC. That is, the memory cell MC may have a circuit structure in which a transistor including the gate electrode 120 and the channel layer 160 and the charge trap layer 140 are connected in parallel.

The memory cell MC may be continuously arranged in a vertical direction with respect to the substrate 101 to constitute a cell string CS. The common source line CSL and the bit line BL may be connected to both ends of the cell string CS, as shown in the circuit diagram of FIG. 4 below. A voltage may be applied to the common source line CSL and the bit line BL so that programming, reading and erasing operations may be performed on a plurality of memory cells MC.

For example, when a memory cell MC to be written is selected, a gate voltage value of a corresponding cell may be adjusted so that no channel may be formed in the selected memory cell MC, e.g., the selected memory cell MC may be in a channel-off state, and gate voltage values of the unselected cells may be adjusted so that the unselected memory cells may be in channel-on states. Thus, a current path by the voltage applied to the common source line CSL and the bit line BL may pass through the selected memory cell MC, and desired information of 1 or 0 may be recorded in the selected memory cell MC.

Even in a reading operation, similarly, reading on the selected cell may be performed. That is, after the gate voltage applied to each gate electrode 120 is adjusted so that the selected memory cell MC is in a channel-off state and the unselected memory cells are in channel-on states, a current flowing through the corresponding cell MC may be measured due to the applied voltage Vread between the common source line CSL and the bit line BL so that a cell state (1 or 0) may be checked.

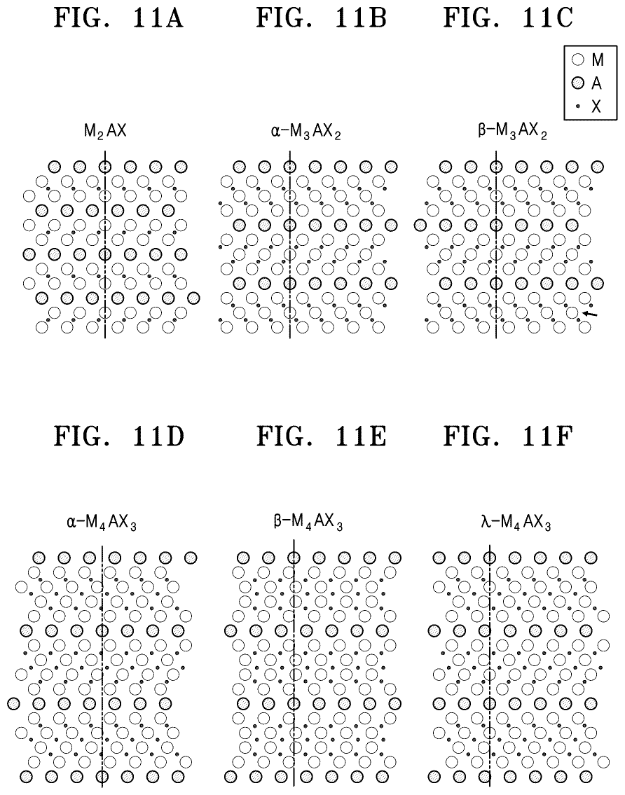

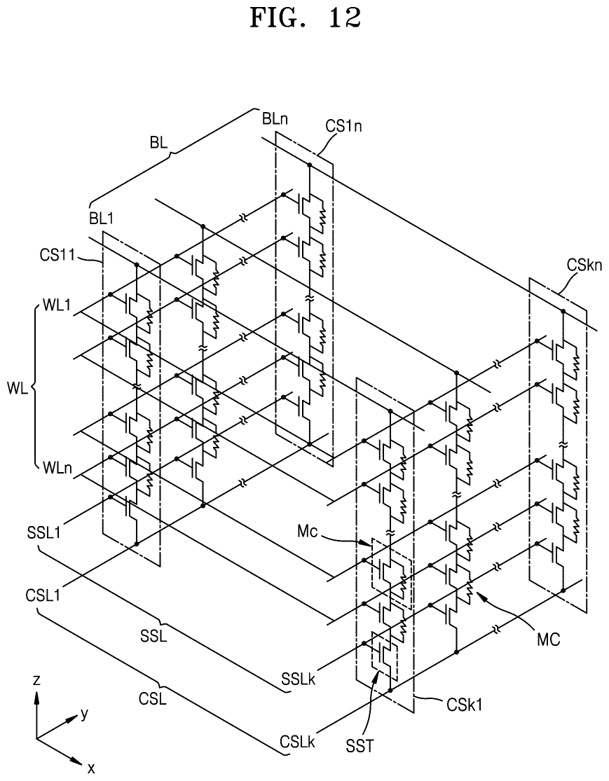

FIGS. 11A to 11F are diagrams showing examples of M, A, and X constituting a gate electrode.

Referring to FIGS. 11A to 11F, M, A, and X may be arranged to have a layered crystal structure. In FIGS. 11A to 11F, solid lines represent virtual lines. M, A, and X may include M₂AX, M₃AX₂, M₄AX₃, or a combination thereof. Referring to FIG. 11A, the composition ratio of M, A, and X may be 2:1:1. Referring to FIGS. 11B and 11C, the composition ratio of M, A, and X may be 3:1:2. Here, α-M₃AX₂ and β-M₃AX₂ may represent polymorphism crystal structures of M₃AX₂, wherein the position of the center A layer of α-M₃AX₂ and the position of the center A layer of β-M₃AX₂ are different from each other. Referring to FIGS. 11D, 11E, and 11F, the composition ratio of M, A, and X may be 4:1:3. Here, α-M₄AX₃, β-M₄AX₃ and γ-M₄AX₃ may represent different polymorphism crystal structure of M₄AX₃. The positions of the M layer, A layer, and X layer are different in α-M₄AX₃, β-MAX₃ and γ-M₄AX₃, respectively.

Nitrogen or carbon included in M, A, and X may have high cohesive energy by covalent bonding with a metal, and thus, electromigration may be improved and resistivity may be improved. In addition, M, A, and X arranged to have a layered crystal structure do not have chemical bonds in the out-of-plane direction and thus may have a high energy barrier for reaction and diffusion between interfaces, and thus, reaction and diffusion between interfaces may be improved.

FIG. 12 is an equivalent circuit diagram of the non-volatile memory device 100 of FIG. 1.

Referring to FIG. 12, k*n of cell strings CS may be provided, may be arranged in a matrix form, and may be referred to as CSij (1≤i≈k, 1≤j≤n) according to each row and column position. Each cell string CSij may be connected to the bit line BL, the string selection line CSL, the word line WL, and the common source line CSL.

Each cell string CSij may include memory cells MC and a string selection transistor SST. Memory cells MC and the string selection transistor SST of each cell string CSij may be stacked in a height direction.

Rows of a plurality of memory cells CS may be connected to different string selection lines SSL1 to SSLk. For example, the string selection transistors SSTs of the cell strings CS11 to CS1n may be commonly connected to the string selection line SSL1. String selection transistors SST of cell strings CSk1 to CSkn may be commonly connected to the string selection line SSLk.

Columns of a plurality of cell strings CS may be connected to different bit lines 190 (BL1 to BLn). For example, memory cells of the cell strings CS11 to CSk1 and the string selection transistors SST may be commonly connected to the bit line 190 (BL1), and the memory cells MC of the cell strings CS1n to CSkn and the string selection transistors SST may be commonly connected to the bit line 190 (BLn).

Rows of a plurality of memory cells CS may be connected to different string selection lines SSL1 to SSLk. For example, the string selection transistors SST of the cell strings CS11 to CS1n may be commonly connected to the common source line CSL1, and the string selection transistors SST of the cell strings CSk1 to CSkn may be commonly connected to the common source line CSLk.

The memory cells MC located at the same heights from the substrate 101 or the string selection transistors SST may be commonly connected to one word line WL, and the memory cells MC located at different heights may be connected to different word lines WL1 to WLm, respectively.

The illustrated circuit structure is illustrative. For example, the number of rows of the cell strings CS may be increased or decreased. As the number of rows of the cell string CS is changed, the number of string selection lines connected to the rows of the cell string CS, and the number of cell strings CS connected to one bit line 190 may also be changed. As the number of rows of the cell string CS is changed, the number of common source lines connected to the rows of the cell strings CS may also be changed.

The number of columns of the cell strings CS may also be increased or decreased. As the number of the columns of the cell string CS is changed, the number of bit lines 190 connected to the columns of the cell strings CS, and the number of the cell string CS connected to one string selection line may also be changed.

The height of the cell string CS may also be increased or decreased. For example, the number of memory cells MC stacked in each cell string CS may be increased or decreased. As the number of memory cells MC stacked in each cell string CS is changed, the number of word lines WL may also be changed. For example, a string selection transistor provided to each cell string CS may be increased. As the number of string selection transistors provided in each cell string CS is changed, the number of string selection lines or the number of common source lines may also be changed. When the number of string selection transistors is increased, the string selection transistors may be stacked in the same form as that of the memory cells MC.

For example, writing and reading may be performed in the unit of rows of the cell strings CS. Cell strings CS may be selected in units of one row by a common source line CSL, and the cell strings CS may be selected in units of one row by the string selection lines SSL. In addition, a voltage may be applied to at least two common source lines CSL as one unit. A voltage may be applied to the entire common source lines CSL as one unit.

In a selected row of the cell strings CS, writing and reading may be performed in units of pages. The page may be one row of memory cells connected to one word line WL. In a selected row of cell strings, memory cells may be selected by word lines WLs in units of pages.

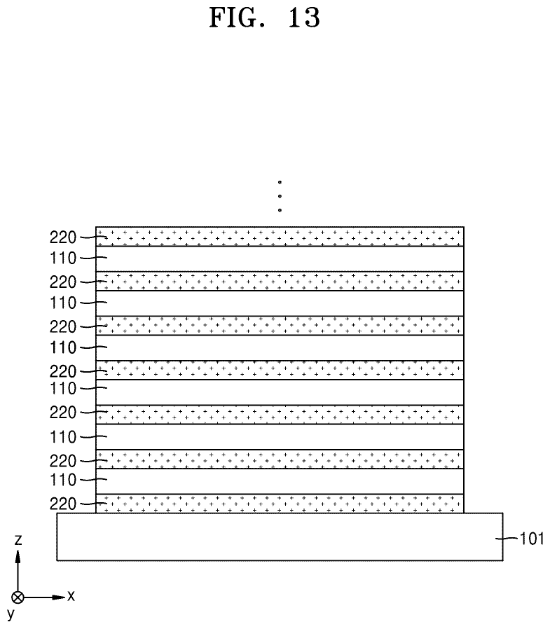

FIGS. 13 to 19D are reference views for describing a method of manufacturing a non-volatile memory device, according to an embodiment.

As shown in FIG. 13, a sacrificial layer 220 and an insulating layer 110 may be alternately stacked on the substrate 101. The sacrificial layer 220 and the insulating layer 110 may be alternately stacked in a direction perpendicular to the surface of the substrate 101. The sacrificial layer 130 may include, for example, a silicon oxide, a silicon nitride, but embodiments are not limited thereto. The sacrificial layer 220 may be formed by various deposition methods such as chemical vapor deposition (CVD), atomic layer deposition (ALD), physical vapor deposition (PVD), and the like.

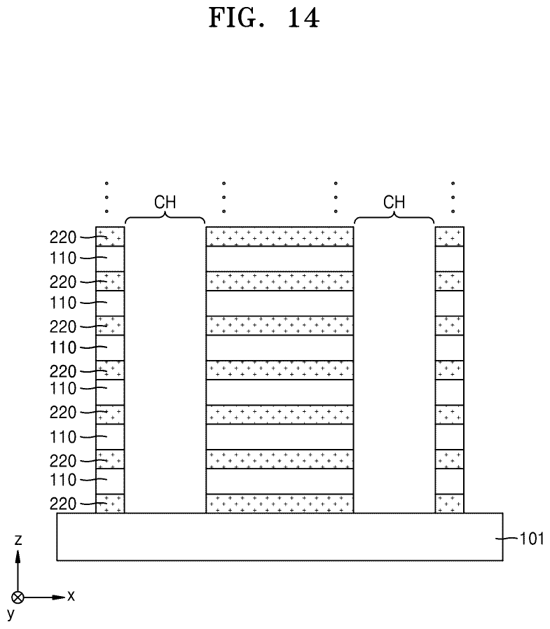

As shown in FIG. 14, a first opening 230 may be formed by anisotropically etching the sacrificial layer 220 and the insulating layer 110 to penetrate the sacrificial layer 220 and the insulating layer 110. A channel hole CH may be formed in the first opening 230. Here, the channel hole CH may be formed to extend in the direction perpendicular to the surface of the substrate 101. The channel hole CH may be formed to have a circular cross-section.

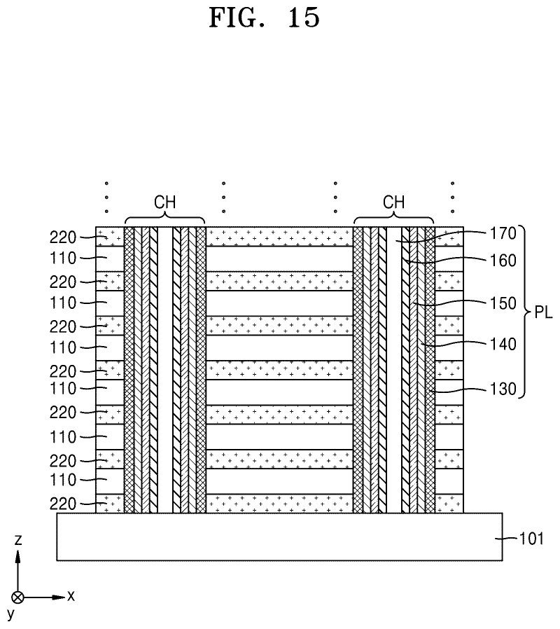

As shown in FIG. 15, a cylindrical pillar PL may be formed on an inner wall of the channel hole CH. The pillar PL may include a plurality of layers. The pillar PL may include a charge blocking layer 130, a charge trap layer 140, a charge tunneling layer 150, a channel layer 160, and a filling layer 170. The charge blocking layer 130, the charge trap layer 140, the charge tunneling layer 150, the channel layer 160, and the filling layer 170 may be sequentially formed on the inner wall of the channel hole CH. The charge blocking layer 130, the charge trap layer 140, the charge tunneling layer 150, the channel layer 160, and the filling layer 170 may be formed to extend in the direction perpendicular to the surface of the substrate 101. The charge blocking layer 130 may be formed on the inner wall of the channel hole CH to be in contact with the sacrificial layer 220 and the insulating layer 110, and the charge trap layer 140 may be formed to be in contact with an inner wall of the charge blocking layer 130, and the charge tunneling layer 150 may be formed to be in contact with the inner wall of the charge trap layer 140. The channel layer 160 may be formed to be in contact with the charge tunneling layer 150. The filling layer 170 may be further formed in the channel layer 160.

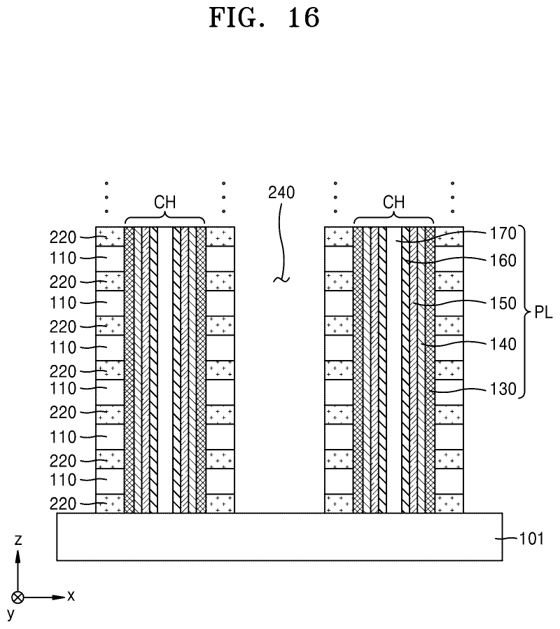

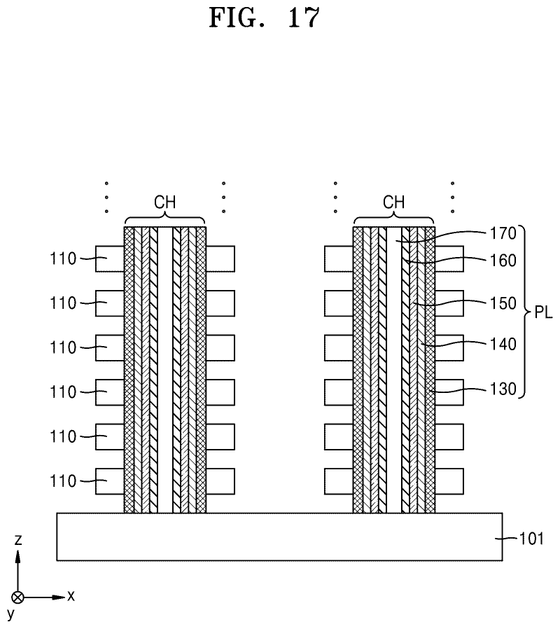

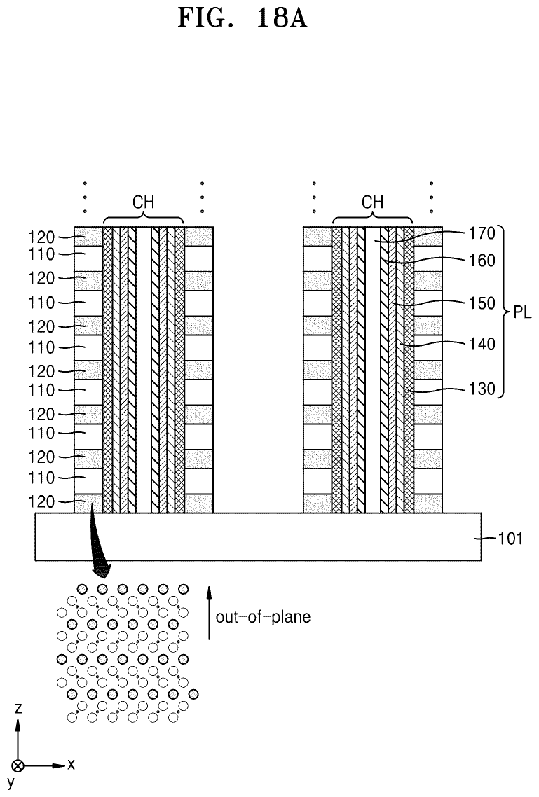

As shown in FIG. 16, a second opening 240 may be formed by etching the sacrificial layers 220 and the insulating layers 110. A portion of the substrate 101 may be exposed through the second opening 240.

As shown in FIG. 17, the sacrificial layer 220 may be removed to expose the insulating layer 110.

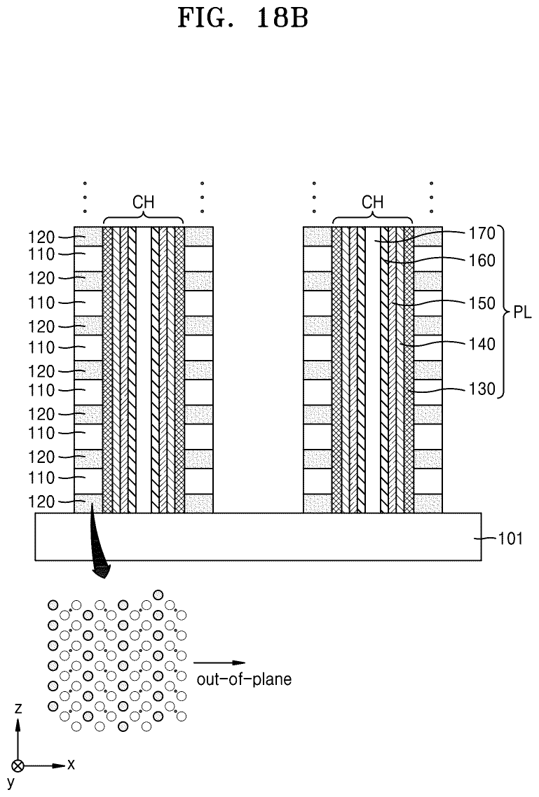

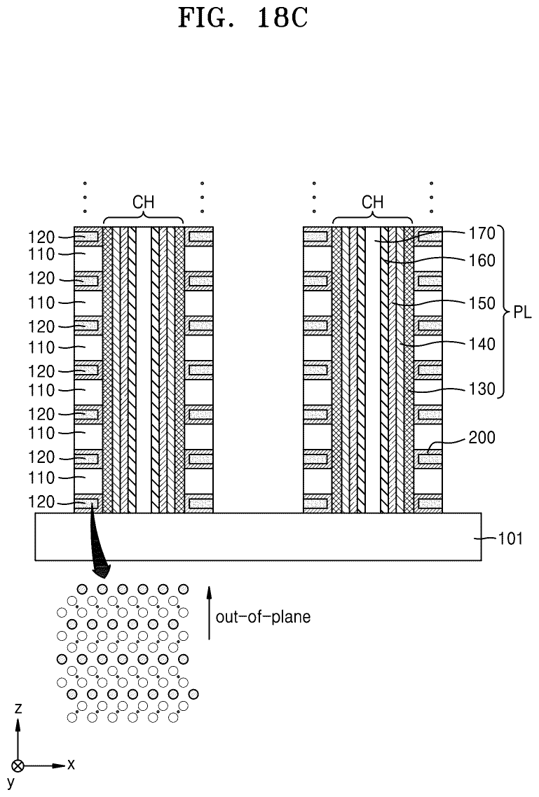

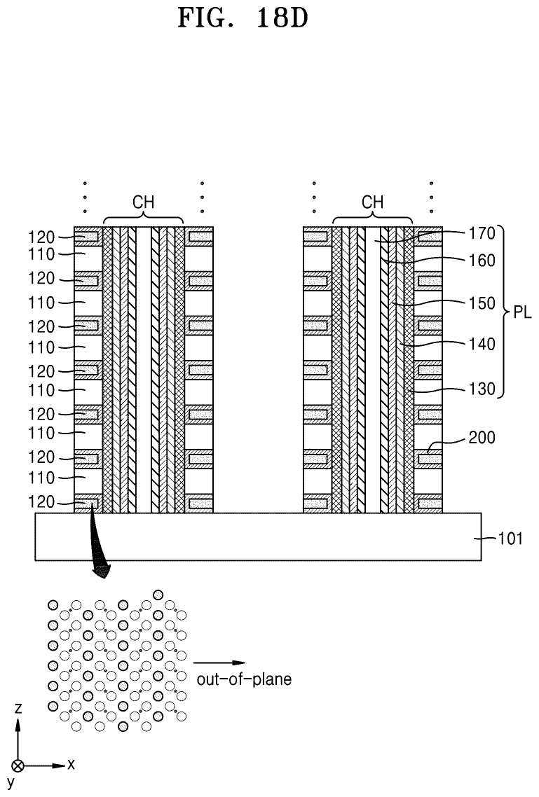

As shown in FIGS. 18A and 18B, the gate electrode 120 may be formed in an area where the sacrificial layer 220 is removed. Alternatively, as shown in FIGS. 18C to 18D, the diffusion barrier layer 200 and the gate electrode 120 may be formed in an area where the sacrificial layer 220 is removed. The gate electrode 120 may include M, A, and X arranged to have a layered crystal structure, and the out-of-plane direction of the layered crystal structure may be parallel to the Z direction as shown in FIGS. 18A and 18C or perpendicular to the Z direction as shown in FIGS. 18B and 18D. M, A, and X of the layered crystal structure of the gate electrode 120 may be formed by sputtering or atomic layer deposition (ALD).

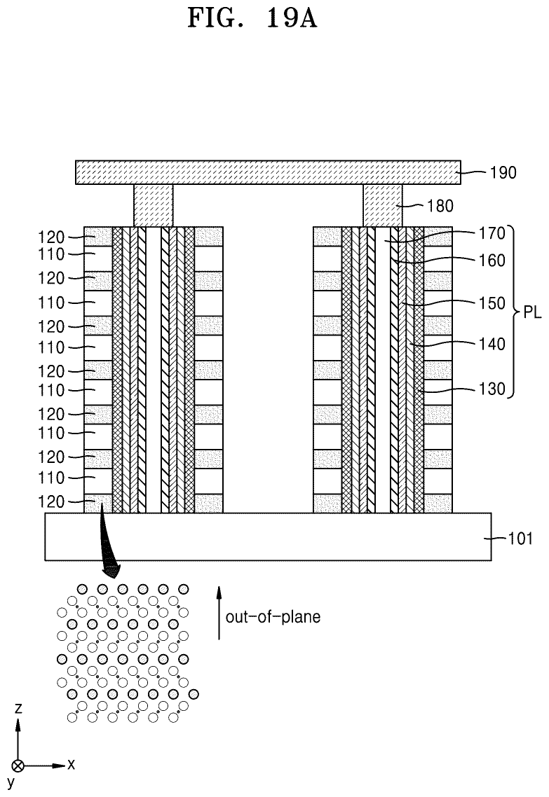

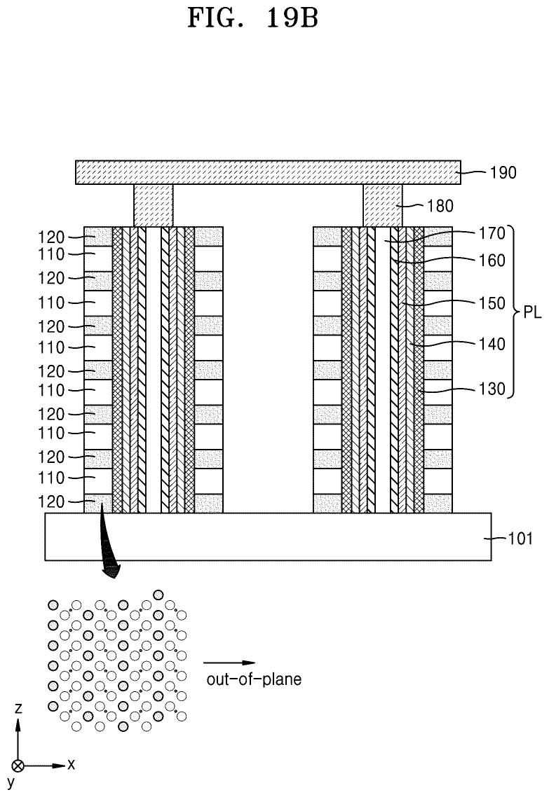

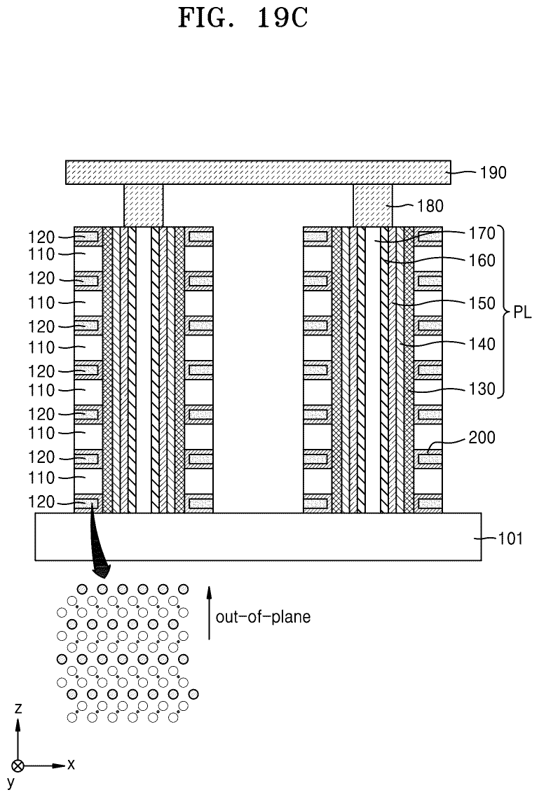

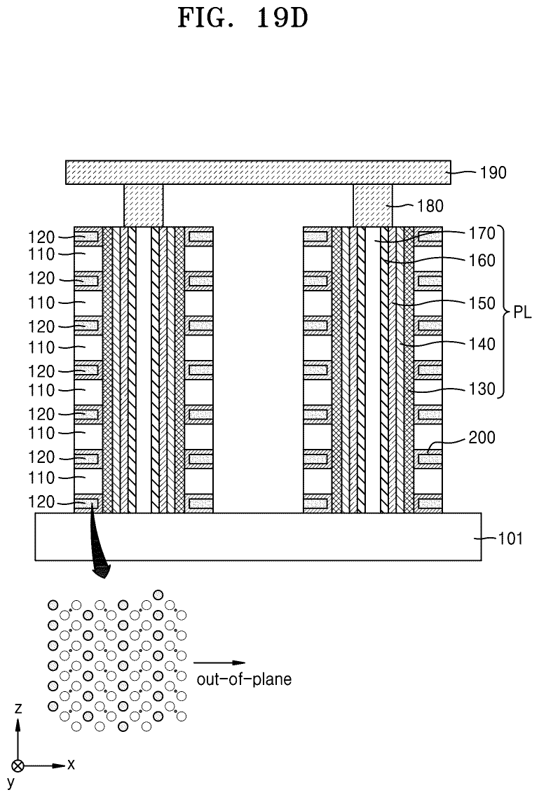

As shown in FIGS. 19A to 19D, a drain 180 may be provided on the pillar PL in FIGS. 18A to 18D. The drain 180 may include a silicon material doped with a second type impurity. For example, the drain 180 may include a silicon material doped with an n-type impurity. A bit line 190 may be provided on the drain 180. The drain 180 and bit lines 190 and 550 may be connected to each other via contact plugs. A doping region may be additionally provided to the substrate 101.

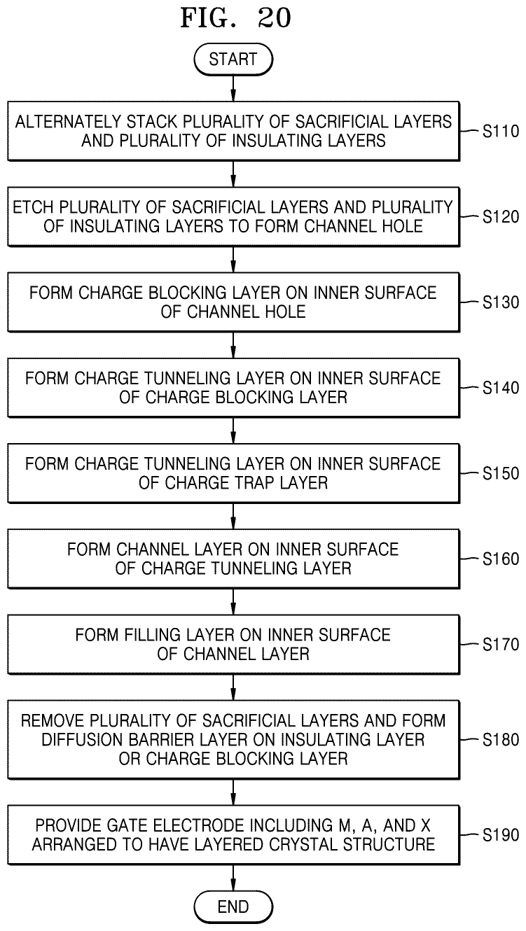

FIG. 20 is a flowchart illustrating a procedure of manufacturing a non-volatile memory device, according to an embodiment.

Referring to FIG. 20, a procedure of manufacturing a non-volatile memory device may include alternately stacking a plurality of sacrificial layers and a plurality of insulating layers (S110), etching the plurality of sacrificial layers and the plurality of insulating layers to form a channel hole (S120), forming a charge blocking layer on an inner surface of the channel hole (S130), forming a charge tunneling layer on an inner surface of the charge blocking layer (S140), forming a charge tunneling layer on an inner surface of the charge trap layer (S150), forming a channel layer on the inner surface of the charge tunneling layer (S160), forming a filling layer on the inner surface of the channel layer (S170), removing the plurality of sacrificial layers and providing a diffusion barrier layer on the insulating layer or the charge blocking layer (S180), and providing a gate electrode including M, A, and X arranged to have a layered crystal structure (S190). In FIG. 20, a procedure in which the providing of the gate electrode (S190) is performed after the providing of the diffusion barrier layer (S180) is shown. However, the providing of the gate electrode (S190) and the providing of the diffusion barrier layer (S180) may be performed together, or the providing of the diffusion barrier layer (S180) may be performed after the providing of the gate electrode (S190).

While FIGS. 13 to 19D and 20 describe methods of manufacturing a non-volatile memory device according to some example embodiments, which include alternately stacking a plurality of sacrificial layers 220 and a plurality of insulating layers 110 (see FIG. 13 and FIG. 20, S110) and then later replacing the sacrificial layers 220 with gate electrodes 120, example embodiments are not limited thereto. In some embodiments, the methods in FIGS. 13 to 19D and 20 may be modified by omitting the sacrificial layers 220. The modified method may include alternately stacking a plurality of gate electrodes 120 and insulating layers 110 on the substrate 101, forming a channel hole CH through the stacking of gate electrodes 120 and insulating layers 110 alternately stacked, forming a pillar PL in the channel hole CH, forming a drain 180 on the pillar PL, and forming a bit line 190 on the drain 180. Optionally, the diffusion barrier layer 200 may be provided between the pillar PL and the gate electrodes 120.

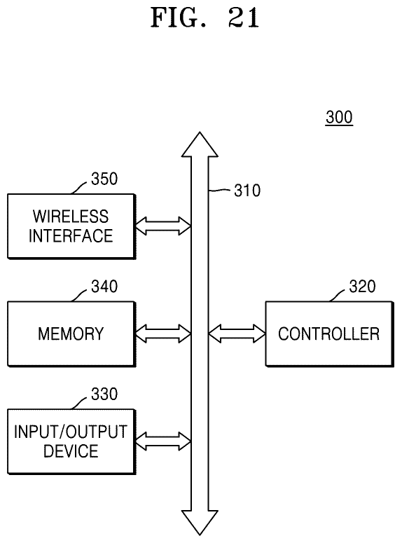

FIG. 21 is a block diagram schematically describing an electronic apparatus 300 including a non-volatile memory device according to an embodiment.

Referring to FIG. 21, the electronic apparatus 300 according to an embodiment may be one of a personal digital assistant (PDA), a laptop computer, a portable computer, a web tablet, a wireless telephone, a mobile phone, a digital music player, a wired/wireless electronic device, or a composite electronic apparatus including at least two of them. The electronic apparatus 300 may include an input/output device 330, such as a controller 320, a keypad, a keyboard, and a display that are combined with each other via a bus 310, a memory 340, and a wireless interface 350.

The controller 320 may include, for example, one or more microprocessors, digital signal processors, microcontrollers, or like. The memory 340 may be used to store command languages executed by the controller 320, for example.

The memory 340 may be used to store user data. The memory 340 may include a non-volatile memory device 100 according to an embodiment.

The electronic apparatus 300 may use the wireless interface 350 so as to transmit data to a wireless communication network for communicating with a radio frequency (RF) signal or to receive data from the wireless communication network. For example, the wireless interface 350 may include an antenna, a wireless transceiver, and the like. The electronic apparatus 300 may be used in a communication interface protocol such as a 3rd communication system such as code division multiple access (CDMA), global system/standard for mobile communications (GSM), naval air development center (NADC), extended time division multiple access (E-TDMA), wideband code division multiple access (WCDAM), or CDMA2000.

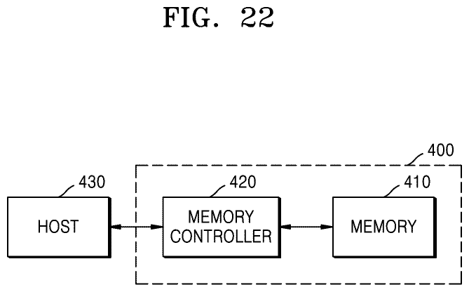

FIG. 22 is a block diagram schematically describing a memory system including a non-volatile memory device according to an embodiment.

Referring to FIG. 22, non-volatile memory devices 100 according to an embodiment may be used to implement a memory system 400. The memory system 400 may include a memory 410 for storing a large amount of data and a memory controller 420. The memory controller 420 may control the memory 410 to read or write stored data from or into the memory 410 in response to a reading/writing request of a host 430. The memory controller 420 may constitute an address mapping table for mapping an address provided from the host 430, for example, a mobile device or a computer system into a physical address of the memory 410. The memory 410 may include a semiconductor memory device 100 according to an embodiment.

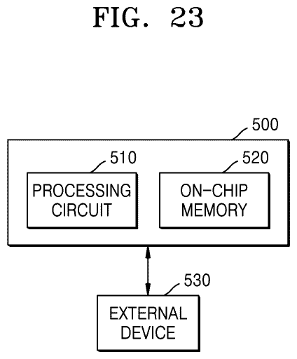

The memory device 100 according to an embodiment described above may be implemented in the form of a chip and may be used as a neuromorphic computing platform. For example, the memory device 100 may be applied to a neuromorphic device of FIG. 23 below.

FIG. 23 is a block diagram schematically illustrating a neuromorphic device including a memory device according to an embodiment.

Referring to FIG. 23, a neuromorphic device 500 may include a processing circuit 510 and/or a memory 520. The memory 520 of the neuromorphic device 500 may include a memory system 400 according to an embodiment.

The processing circuit 510 may be configured to control functions for driving the neuromorphic device 500. For example, the processing circuit 510 may execute a program stored in the memory 520 of the neuromorphic device 500 to control the neuromorphic device 500.

The processing circuit 510 may include a combination of hardware such as a logic circuit and software for executing software, or a combination thereof. For example, the processor may include a central processing unit (CPU), a graphics processing unit (GPU), an application processor (AP) within the neuromorphic device 500, an arithmetic logic unit (ALU), a digital processor, a microcomputer, a field programmable gate array (FPCA), System-on-Chip (SoC), a programmable logic unit, an application-specific integrated circuit (ASIC), or the like.

Also, the processing circuit 510 may read/write various data from/into an external device 1030 and may execute the neuromorphic device 500 using the data. The external device 1030 may include a sensor array including an external memory and/or an image sensor (e.g., a CMOS image sensor circuit).

The neuromorphic device 500 shown in FIG. 23 may be applied to a machine learning system. The machine learning system may utilize various artificial neural network organizations and processing models, including, for example, a convolutional neural network (CNN), a convolutional neural network, a long short-term memory (LSTM network), and/or a gated recurrent unit (GRU), a deep belief network (SNN), generative adversarial networks (SSDNN), restricted Boltzmann networks (RBM), and the like.

Such machine learning systems may include, for example, linear regression and/or logistic regression, statistical clustering, Bayesian classification, decision trees, dimensionality reduction such as principal component analysis, and other types of machine learning models, such as expert systems, and/or combinations thereof, including ensemble techniques such as random forest. The machine learning model may be used to provide various services such as an image classification service, biometric information or biometric data, a user authentication service based on biometric information or biometric data, an advanced driver assistance system (ADAS), a voice assistant service, an automatic speech recognition (ASR) service, and the like, and may be installed and executed in another electronic apparatus.

In the non-volatile memory device and the method of manufacturing the same, described above, a non-volatile memory that limits and/or prevents reaction or diffusion between interfaces and has improved resistivity may be provided.

In the non-volatile memory device and the method of manufacturing the same, described above, a non-volatile memory, in which low power and high integration may be easily implemented, may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A non-volatile memory device comprising:
a channel layer extending in a first direction;
a plurality of gate electrodes and a plurality of insulating layers spaced apart from the channel layer and alternately arranged in the first direction;
a charge trap layer between the channel layer and the plurality of gate electrodes; and
a charge tunneling layer between the channel layer and the charge trap layer, wherein
each of the plurality of gate electrodes includes M, A, and X,
M includes a metal,
A includes a Group 13 element, a Group 14 element, or V, or a combination thereof,
X includes carbon or nitrogen, and
M, A, and X are arranged to have a layered crystal structure.

2. The non-volatile memory device of claim 1, wherein each of the plurality of gate electrodes includes M₂AX, M₃AX₂, or M₄AX₃, or a combination thereof.

3. The non-volatile memory device of claim 1, wherein M includes Cr, Ti, V, Ta, Mo, Hf, or Zr, or a combination thereof.

4. The non-volatile memory device of claim 1, wherein A includes Si, Al, Ga, In, Ge, Sn, or V, or a combination thereof.

5. The non-volatile memory device of claim 1, wherein an out-of-plane direction of the layered crystal structure is parallel to the first direction.

6. The non-volatile memory device of claim 1, wherein an out-of-plane direction of the layered crystal structure is perpendicular to the first direction.

7. The non-volatile memory device of claim 1, further comprising:
a diffusion barrier layer between the plurality of gate electrodes and the plurality of insulating layers.

8. The non-volatile memory device of claim 1, further comprising:
a diffusion barrier layer between the plurality of gate electrodes and the charge trap layer.

9. The non-volatile memory device of claim 1, further comprising:
a diffusion barrier layer between the plurality of gate electrodes and the plurality of insulating layers, wherein
the diffusion barrier layer is between the plurality of gate electrodes and the charge trap layer.

10. The non-volatile memory device of claim 1, further comprising:
a charge blocking layer between the charge trap layer and the plurality of gate electrodes.

11. A method of manufacturing a non-volatile memory device, the method comprising:
alternately stacking a plurality of sacrificial layers and a plurality of insulating layers, in a first direction;
forming a channel hole by etching through a region of the plurality of sacrificial layers and the plurality of insulating layers;
providing a charge trap layer on an inner surface of the channel hole;
providing a charge tunneling layer on an inner surface of the charge trap layer;
providing a channel layer on an inner surface of the charge tunneling layer; and
removing the plurality of sacrificial layers and providing a plurality of gate electrodes in an area in which the plurality of sacrificial layers were removed, wherein
each of the plurality of gate electrodes includes M, A, and X,
M includes a metal,
A includes a Group 13 element, a Group 14 element, or V, or a combination thereof,
X includes carbon or nitrogen, and
M, A, and X are arranged to have a layered crystal structure.

12. The method of claim 11, wherein each of the gate electrodes includes M₂AX, M₃AX₂, or M₄AX₃, or a combination thereof.

13. The method of claim 11, wherein M includes Cr, Ti, V, Ta, Mo, Hf, or Zr, or a combination thereof.

14. The method of claim 11, wherein A includes Si, Al, Ga, In, Ge, Sn, or V, or a combination thereof.

15. The method of claim 11, wherein an out-of-plane direction of the layered crystal structure is parallel to the first direction.

16. The method of claim 11, wherein an out-of-plane direction of the layered crystal structure is perpendicular to the first direction.

17. The method of claim 11, further comprising:
providing a diffusion barrier layer between the plurality of gate electrodes and the plurality of insulating layers or between the plurality of gate electrodes and the charge trap layer.

18. The method of claim 11, further comprising:
providing a charge blocking layer between the charge trap layer and the plurality of gate electrodes.
